(19) United States
(12) Patent Application Publication
(10) Pub. No.: US 2020/0312738 A1
(43) Pub. Date: Oct. 1, 2020

(54) THERMAL MANAGEMENT SOLUTIONS USING COMPARTMENTALIZED PHASE CHANGE MATERIALS

(71) Applicant: Intel Corporation, Santa Clara, CA (US)

(72) Inventors: Junnan Zhao, Gilbert, AZ (US); Cheng Xu, Chandler, AZ (US); Zhimin Wan, Chandler, AZ (US); Yikang Deng, Chandler, AZ (US); Chong Zhang, Chandler, AZ (US); Ying Wang, Chandler, AZ (US)

(73) Assignee: Intel Corporation, Santa Clara, CA (US)

(21) Appl. No.: 16/364,540

(22) Filed: Mar. 26, 2019

(51) Int. Cl. H01L 23/373; H01L 21/768; H01L 23/367

(52) U.S. Cl. CPC H01L 23/373; H01L 23/367; H01L 21/76841

(57) ABSTRACT

An integrated circuit assembly may be formed having at least one integrated circuit device electrically attached to an electronic substrate. The integrated circuit assembly may further include at least one heat dissipation device attached to the electronic substrate, wherein the at least one heat dissipation device comprises a phase change material within a containment chamber. The at least one integrated circuit device may be thermally connected to the at least one heat dissipation device with at least one heat transfer structure formed in or on the electronic substrate.

### TECHNICAL FIELD

Embodiments of the present description generally relate to the removal of heat from integrated circuit devices, and, more particularly, to thermal management solutions using phase change materials which are contained within compartments.

### BACKGROUND

Higher performance, lower cost, increased miniaturization, and greater packaging density of integrated circuits within integrated circuit devices are ongoing goals of the electronics industry. As these goals are achieved, the density of power consumption of components within the integrated circuit devices has increased, which, in turn, increases the average junction temperature of the integrated circuit device. If the temperature of the integrated circuit device becomes too high, circuits within the integrated circuit device may be damaged or destroyed. This is a particular problem when the integrated circuit device of the integrated circuit package has a specific area or areas that generate greater heat than other areas of the integrated circuit device during operation. These areas are known as hot spots and are particularly susceptible to thermal damage. Thus, heat spreaders may be attached to the integrated circuit package to remove heat. However, the use of heat spreaders may be impractical in some applications for technical reasons such as height or Z-direction restrictions and/or cost reasons.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly having a heat dissipation device in thermal contact with an integrated circuit device, according to an embodiment of the present description.

FIG. 2 is a side cross-sectional view of an integrated circuit assembly having a heat dissipation device in thermal contact with an integrated circuit device, according to another embodiment of the present description.

FIGS. 3-8 are plan views along view A-A of either FIG. 1 or FIG. 2 illustrating the integrated circuit assembly having a heat dissipation device in thermal contact with an integrated circuit device, according to various embodiments of the present description.

FIG. 9 is a flow diagram of a method for fabricating an integrated circuit assembly, according to various embodiments of the present description.

FIG. 10 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include an integrated circuit assembly having at least one integrated circuit device electrically attached to an electronic substrate. The integrated circuit assembly may further include at least one heat dissipation device attached to the electronic substrate, wherein the at least one heat dissipation device comprises a phase change material within a containment chamber. The at least one integrated circuit device may be thermally connected to the at least one heat dissipation device with at least one heat transfer structure formed in or on the electronic substrate.

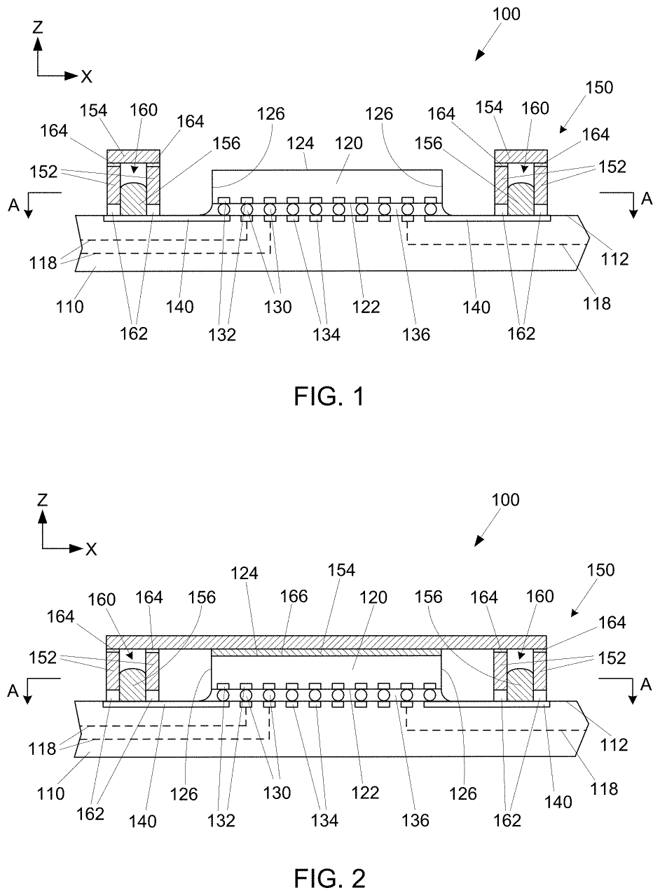

As shown in FIG. 1, an integrated circuit assembly 100, such as an integrated circuit package, may be formed by first providing or forming an electronic substrate 110, such as an interposer, a printed circuit board, a motherboard, or the like. At least one integrated circuit device 120 may be attached to a first surface 112 of the electronic substrate 110 with a plurality of interconnects 130. The plurality of interconnects 130 may extend between bond pads 132 formed in or on a first surface 122 (also known as the “active surface”) of the integrated circuit device 120, and substantially mirror-image bond pads 134 in or on the first surface 112 of the electronic substrate 110. The at least one integrated circuit device 120 may further include a second surface 124 (also known as the “back surface”) opposing the first surface 122 and at least one side 126 extending between the first surface 122 and the second surface 124 of the at least one integrated circuit device 120. The least one integrated circuit device 120 may be any appropriate device, including, but not limited to, a microprocessor, a multichip package, a chipset, a graphics device, a wireless device, a memory device, an application specific integrated circuit device, combinations thereof, stacks thereof, or the like. The interconnects 130 may be any appropriate electrically conductive material or structure, including but not limited to, solder balls, metal bumps or pillars, metal filled epoxies, or a combination thereof. In one embodiment, the interconnects 130 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment, the interconnects 130 may be copper bumps or pillars. In a further embodiment, the interconnects 130 may be metal bumps or pillars coated with a solder material.

An underfill material 136, such as an epoxy material, may be disposed between the first surface 122 of the integrated circuit device 120 and the first surface 112 of the electronic substrate 110, and surrounding the plurality of interconnects 130. As will be understood to those skilled in the art, the underfill material 136 may be dispensed between the first surface 122 of the integrated circuit device 120 and the first surface 112 of the electronic substrate 110 as a viscous liquid and then hardened with a curing process. The underfill material 136 may also be a molded underfill material. The underfill material 136 may provide structural integrity and may prevent contamination, as will be understood to those skilled in the art.

As further shown in FIG. 1, the electronic substrate 110 may provide electrical communication through conductive routes 118 (illustrated as dashed lines) between the integrated circuit device 120 and external components (not shown). As will be understood to those skilled in the art, the bond pads 132 of the integrated circuit device 120 may be in electrical communication with integrated circuitry (not shown) within the integrated circuit device 120.

The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. The conductive routes 118 may be a combination of conductive traces (not shown) and conductive vias (not shown) that extend through the plurality of dielectric material layers (not shown). These conductive traces and conductive vias, and processes of forming the same, are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood by those skilled in the art, the electronic substrate 110 may be a cored substrate or a coreless substrate.

As shown in FIG. 1, the electronic substrate 110 may include at least one heat transfer structure 140 formed in or on the electronic substrate 110. The at least one heat transfer structure 140 may be made of any appropriate thermally conductive material. In one embodiment, the at least one heat transfer structure 140 may comprises a metal, including, but not limited to copper, silver, nickel, gold, aluminum, alloys thereof, and the like. In another embodiment, the at least one heat transfer structure 140 may comprise metal filled epoxies and he like. The at least one heat transfer structure 140 may be formed during the fabrication of the electronic substrate 110, such as during at least one metallization step, as will be understood to those skilled in the art. Although the at least one heat transfer structure 140 is illustrated as being at the first surface 112 for the electronic substrate 110, it is understood that at least a portion of the at least one heat transfer structure 140 may be embedded below the first surface 112 of the electronic substrate 110.

As further shown in FIG. 1, a heat dissipation device 150 may be formed on the electronic substrate 110. The heat dissipation device 150 may include at least one sidewall 152 extending from the first surface 112 of the electronic substrate 110 and a capping structure 154 attached to the at least one sidewall 152. The combination of a portion of the at least one heat transfer structure 140, the at least one sidewall 152, and the capping structure 154 may form a containment chamber 160, wherein a phase change material 156 is disposed within the containment chamber 160. In one embodiment, the heat dissipation device 150 may have little or no impact with the height (Z-direction) of the integrated circuit assembly 100.

The phase change material 156 may be a substance with a high heat of fusion, which, when it melts and solidifies, is capable of storing and releasing large amounts of thermal energy. In an embodiment of the present description, the phase change material may include, but is not limited to, paraffin wax, nonadecane, decanoic (capric) acid, eicosane, dodecanoic (lauric) acid, docosane, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof.

The at least one sidewall 152 and the capping structure 154 may be formed from any appropriate thermally conductive material, including, but not limited to copper, aluminum, and the like. The at least one sidewall 152 of the heat dissipation device 150 may be attached to the electronic substrate 110, and the capping structure 154 may be attached to the at least one sidewall 152 by any known thermally conductive material, including but not limited to a solder material, a metal filled epoxy adhesive, and the like. In one embodiment, the at least one sidewall 152 of heat dissipation device 150 may extend substantially perpendicularly to the first surface 112 of the electronic substrate 110. It is understood that the term substantially perpendicular includes the at least one sidewall 152 being plus or minus 5 degrees from 90 degrees.

As further shown in FIG. 1, the at least one heat transfer structure 140 may extend between and be in thermal contact with the at least one integrated circuit device 120 and the heat dissipation device 150. In one embodiment, the at least one heat transfer structure 140 may be in direct contact with the phase change material 156 in the containment chamber 160 of the heat dissipation device 150. In another embodiment of the present description, the at least one heat transfer structure 140 may be in thermal contact with the at least one integrated circuit device 120 through at least one of the plurality of interconnects 130, which is attached to the at least one heat transfer structure 140. The at least one heat transfer structure 140 may be electrically non-functional, or may serve as a power plane, a ground plane, or receive/transmit electrical signals, as will be understood to those skilled in the art.

During the operation of the integrated circuit assembly 100, the at least one integrated circuit device 120 will heat up. This heat may be transferred through the at least one heat transfer structure 140 to the heat dissipation device 150, where the heat is dissipated by the phase change material 156 in the containment chamber 160. As will also be understood by those skilled in the art, the heat dissipation device 150 may also serve as a stiffener for the integrated circuit assembly 100.

In a further embodiment of the present description, as shown in FIG. 2, the capping structure 154 may extend over the second surface 124 of the integrated circuit device 120, and a thermal interface material 166 may be disposed between the capping structure 154 of the heat dissipation device 150 and the second surface 124 of the integrated circuit device 120. The thermal interface material 166 may include any appropriate material, including, but not limited to, a thermal grease, a thermal adhesive, a thermal tape, and the like, as known in the art.

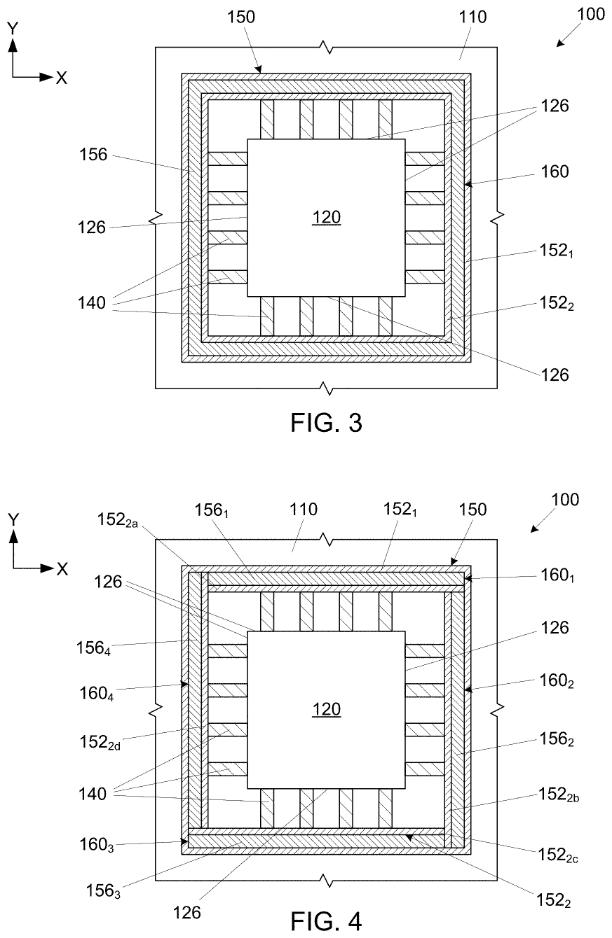

As shown in FIG. 3, in one embodiment of the present description, the heat5 dissipation device 150 may comprise an inner wall 152₂ that surrounds the integrated circuit device 120 and an outer wall 152₁ that surrounds the inner wall 152₂ with the phase change material 156 dispose between the inner wall 152₂ and the outer wall 152₁. Such a configuration results in a single containment chamber 160 and a phase change material 156 disposehd therein.

In another embodiment of the present description, the heat dissipation device 150 may be configured to have multiple containment chambers. As shown in FIG. 4, the inner wall 152₂ may be made of multiple segments, shown as four segments 152₂ₐ, 152_{2b}, 152_{2c}, and 152_{2d}, which contact the outer wall 152₁ in specific locations to form multiple containment chambers, shown as four containment chambers 160₁, 160₂, 160₃, and 160₄. Thus, with such a multiple containment chamber configuration, at least one different phase change material 156₁, 156₂, 156₃, and 156₄ may be placed within a respective containment chamber 160₁, 160₂, 160₃, and 160₄. As will understood to those skilled in the art, this will allow the heat dissipation device 150 to be tuned to the specific heat profile of the integrated circuit device 120.

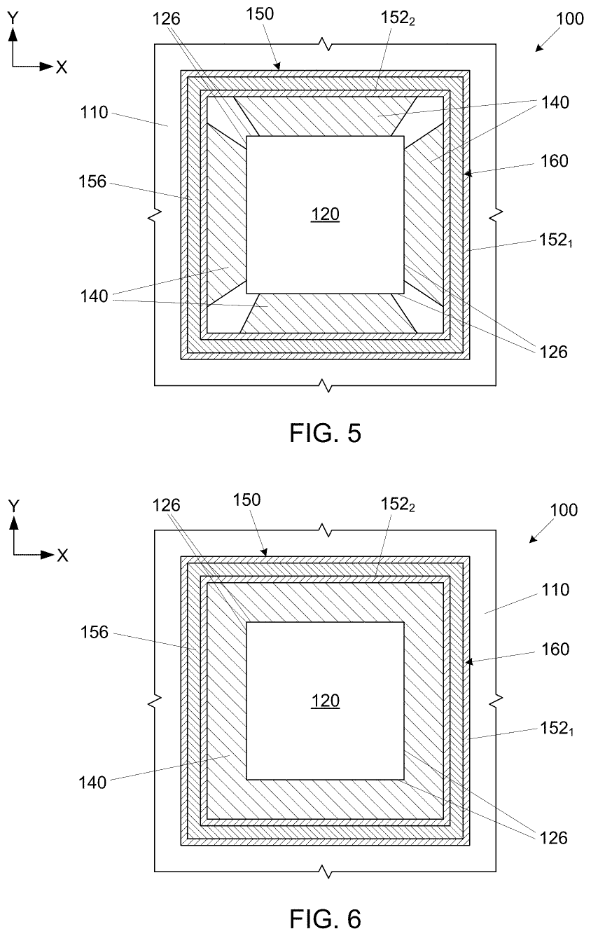

The at least one heat transfer structure 140 may have any appropriate configuration in the X and Y directions. In the embodiments illustrated in FIGS. 3 and 4, at least one heat transfer structure 140 may be a plurality of heat transfer structures 140 extending from each of the sides 126 of the integrated circuit device 120 to the heat dissipation device 150. In one embodiment, the plurality of heat transfer structures 140 may be substantially symmetrically distributed around the integrated circuit device 120. In the embodiment illustrated in FIG. 5, the plurality of heat transfer structures 140 may each comprise a single structure extending from each side 126 of the integrated circuit device 120 to the heat dissipation device 150. In a further embodiment shown in FIG. 6, the at least one heat transfer structure 150 may be a single structure that substantially surrounds the integrated circuit device 120 and extends from the integrated circuit device 120 to the heat dissipation device 150.

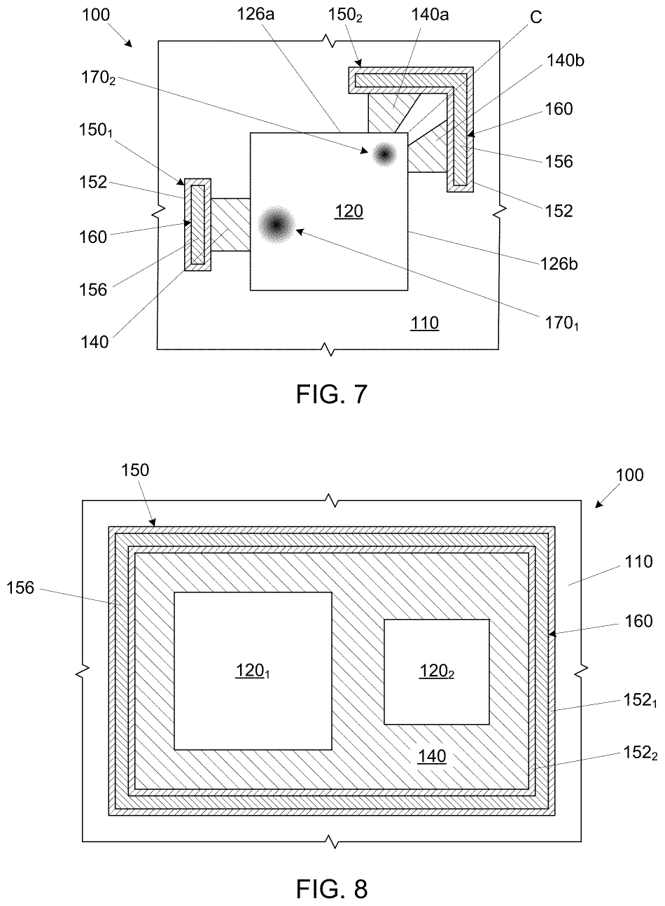

The embodiments of the present description shown in FIGS. 3-6 are configurations of the heat dissipation devices 140 and heat transfer structures 150 which may dissipate heat from the integrated circuit device 120 in a relatively uniform manner. However, the embodiments of the present description may be directed to configurations which remove heat from specific hotspots 170₁, 170₂ within the integrated circuit device 120, as shown in FIG. 7. In one embodiment on the left side of FIG. 7, a first heat dissipation device 150₁ may be formed with the single sidewall 152 forming the containment chamber 160 and surrounding the phase change material 156 with one heat transfer structure 140 extending between the integrated circuit device 120 proximate the hotspot 170₁ and the first heat dissipation device 150₁. In another embodiment on the right side of FIG. 7, a second heat dissipation device 150₂ may be formed with the single sidewall 152 forming the containment chamber 160 in an L-shape at a corner C of the integrated circuit device 120 and surrounding the phase change material 156 with one heat transfer structure 140a extending between one side 126a of the integrated circuit device 120 proximate the hotspot 170₂ and the second heat dissipation device 150₂, and another heat transfer structure 140b extending between another side 126b of the integrated circuit device 120 proximate the hotspot 170₂ and the second heat dissipation device 150₂.

Although FIGS. 1-7 illustrate embodiments with a single integrated circuit device 120, the embodiments of the present description are not so limited. For example, as shown in FIG. 8, multiple integrated circuit devices, such as first integrated circuit device 1201 and second integrated circuit device 120₂, may be accommodated by a single heat dissipation structure 150.

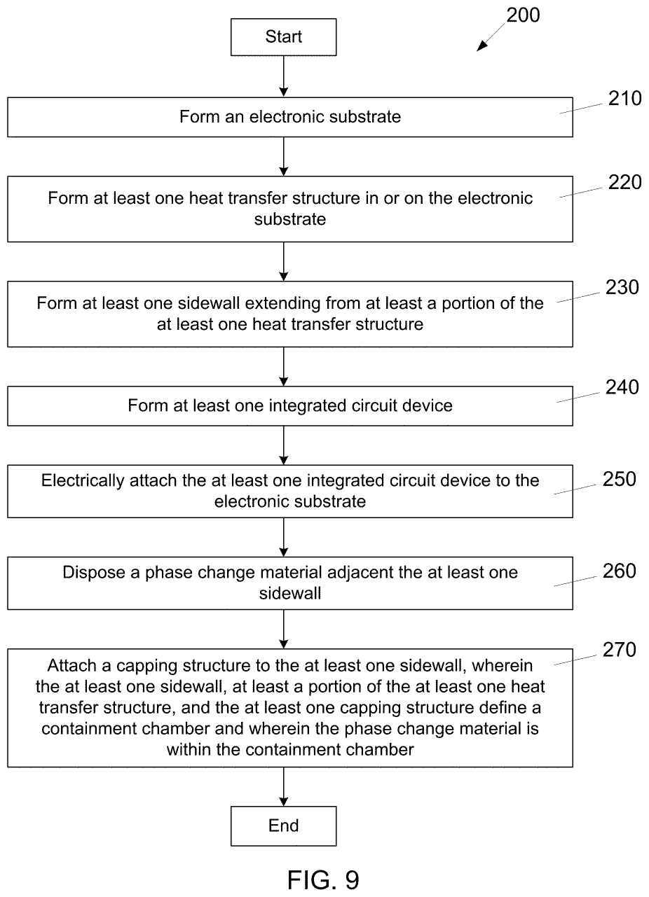

FIG. 9 is a flow chart of a process 200 of fabricating an integrated circuit assembly according to an embodiment of the present description. As set forth in block 210, an electronic substrate may be formed. At least one heat transfer structure may be formed in or on the electronic substrate, as set forth in block 220. As set forth in block 230, at least one sidewall may be formed to extend from at least a portion of the at least one heat transfer structure. At least one integrated circuit device may be formed, as set forth in block 240. As set forth in block 250, the at least one integrated circuit device may be electrically attached to the electronic substrate. A phase change material may be disposed adjacent the at least one sidewall, as set forth in block 260. As set forth in block 270, a capping structure may be attached to the at least one sidewall, wherein the at least one sidewall, at least a portion of the at least one heat transfer structure, and the at least one capping structure define a containment chamber and wherein the phase change material is within the containment chamber.

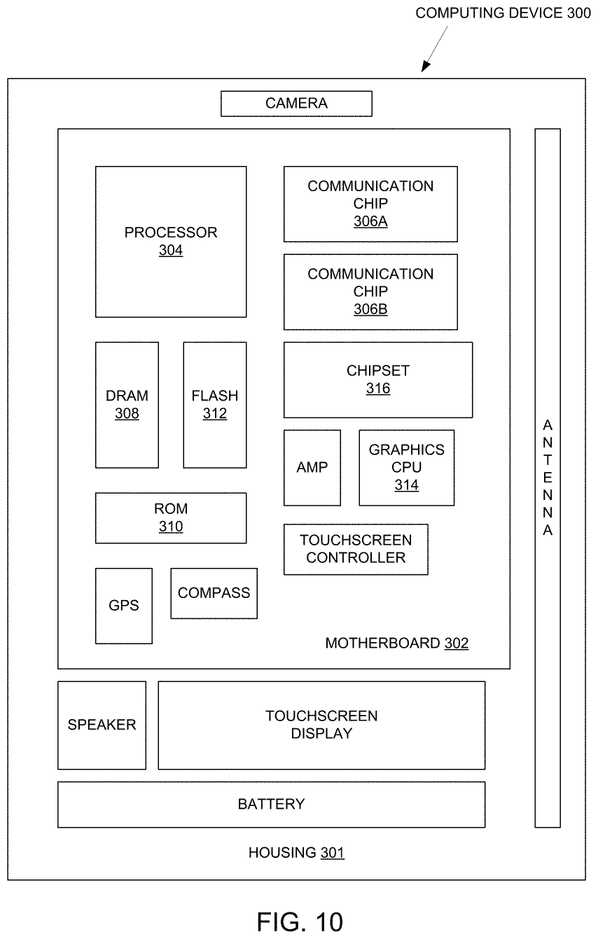

FIG. 10 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device electronic data from registers and/or memory to transform that electronic data into other electronic data that may be stored in registers and/or memory.

At least one of the integrated circuit components may include an electronic substrate, at least one integrated circuit device electrically attached to the electronic substrate, at least one heat dissipation device attached to the electronic substrate, wherein the at least one heat dissipation device comprises a phase change material within a containment chamber, and at least one heat transfer structure formed in or on the electronic substrate, wherein the at least one heat transfer structure extends between and thermally contacts the at least one integrated circuit device and the at least one heat dissipation device.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-10. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an integrated circuit assembly, comprising an electronic substrate, at least one integrated circuit device electrically attached to the electronic substrate, at least one heat dissipation device attached to the electronic substrate, wherein the at least one heat dissipation device comprises a phase change material within a containment chamber, and at least one heat transfer structure formed in or on the electronic substrate, wherein the at least one heat transfer structure extends between and thermally contacts the at least one integrated circuit device and the at least heat dissipation device.

In Example 2, the subject matter of Example 1 can optionally include the at least one integrated circuit device thermally contacting the at least one integrated circuit device through at least one interconnect.

In Example 3, the subject matter of either Example 1 or 2 can optionally include the at least one heat dissipation device comprises an inner sidewall surrounding the at least one integrated circuit device and an outer sidewall surrounding the inner sidewall, and a capping structure extending between the inner wall and the outer wall.

In Example 4, the subject matter of any of Examples 1 to 3 can optionally include the capping structure extending over the integrated circuit device.

In Example 5the subject matter of Example 4 can optionally include the capping structure being in thermal contact with the integrated circuit device by a thermal interface material disposed therebetween.

In Example 6, the subject matter of any of Examples 1 to 5 can optionally include the at least one heat dissipation device including a plurality of containment chambers.

In Example 7, the subject matter of Example 6 can optionally include one containment chamber of the plurality of containment chambers contains a phase change material and wherein another containment chamber of the plurality of containment chambers contains a different phase change material.

In Example 8, the subject matter of any of Examples 1 to 7 can optionally include the at least one heat transfer structure comprises a single structure substantially surrounding the at least one integrated circuit device.

In Example 9, the subject matter of any of Examples 1 to 7 can optionally include the at least one integrated circuit device including a plurality of sides and wherein the at least one heat transfer structure comprises at least one heat transfer structure extending between each of the plurality sides of the at least one integrated circuit device and the at least one heat dissipation device.

Example 10 is an electronic system comprising a board; and an integrated circuit package electrically attached to the board, wherein the integrated circuit assembly comprises an electronic substrate, at least one integrated circuit device electrically attached to the electronic substrate, at least one heat dissipation device attached to the electronic substrate, wherein the at least one heat dissipation device comprises a phase change material within a containment chamber, and at least one heat transfer structure formed in or on the electronic substrate, wherein the at least one heat transfer structure extends between and thermally contacts the at least one integrated circuit device and the at least heat dissipation device.

In Example 11, the subject matter of Example 10 can optionally include the at least one integrated circuit device thermally contacting the at least one integrated circuit device through at least one interconnect.

In Example 12, the subject matter of either Example 10 or 11 can optionally include the at least one heat dissipation device comprises an inner sidewall surrounding the at least one integrated circuit device and an outer sidewall surrounding the inner sidewall, and a capping structure extending between the inner wall and the outer wall.

In Example 13, the subject matter of any of Examples 10 to 12 can optionally include the capping structure extending over the integrated circuit device.

In Example 14, the subject matter of Example 13 can optionally include the capping structure being in thermal contact with the integrated circuit device by a thermal interface material disposed therebetween.

In Example 15, the subject matter of any of Examples 10 to 14 can optionally include the at least one heat dissipation device including a plurality of containment chambers.

In Example 16, the subject matter of Example 15 can optionally include one containment chamber of the plurality of containment chambers contains a phase change material and wherein another containment chamber of the plurality of containment chambers contains a different phase change material.

In Example 17, the subject matter of any of Examples 10 to 16 can optionally include the at least one heat transfer structure comprises a single structure substantially surrounding the at least one integrated circuit device.

In Example 18, the subject matter of any of Examples 10 to 16 can optionally include the at least one integrated circuit device including a plurality of sides and wherein the at least one heat transfer structure comprises at least one heat transfer structure extending between each of the plurality sides of the at least one integrated circuit device and the at least one heat dissipation device.

In Example 19 is a method of fabrication an integrated circuit assembly may comprise forming an electronic substrate, forming at least one heat transfer structure in or on the electronic substrate, forming at least one sidewall extending from at least a portion of the at least one heat transfer structure, forming at least one integrated circuit device, electrically attaching the at least one integrated circuit device to the electronic substrate, disposing a phase change material adjacent the at least one sidewall, and attaching a capping structure to the at least one sidewall, wherein the at least one sidewall, at least a portion of the at least one heat transfer structure, and the at least one capping structure define a containment chamber and wherein the phase change material is within the containment chamber.

In Example 20, the subject matter of Example 19 can optionally include the at least one integrated circuit device thermally contacting the at least one integrated circuit device through at least one interconnect.

In Example 21, the subject matter of either Example 19 or 20 can optionally include forming the at least one heat dissipation device comprising forming an inner sidewall surrounding the at least one integrated circuit device and forming an outer sidewall surrounding the inner sidewall, and forming a capping structure extending between the inner wall and the outer wall.

In Example 22, the subject matter of any of Examples 19 to 21 can optionally include forming the capping structure to extend over the integrated circuit device.

In Example 23, the subject matter of Example 22 can optionally include thermally contacting the capping structure with the integrated circuit device by a thermal interface material disposed therebetween.

In Example 24, the subject matter of any of Examples 19 to 23 can optionally include forming the at least one heat dissipation device including a plurality of containment chambers.

In Example 25, the subject matter of Example 24 can optionally include one containment chamber of the plurality of containment chambers contains a phase change material and wherein another containment chamber of the plurality of containment chambers contains a different phase change material.

In Example 26, the subject matter of any of Examples 19 to 25 can optionally include forming the at least one heat transfer structure comprising forming a single structure substantially surrounding the at least one integrated circuit device.

In Example 27, the subject matter of any of Examples 19 to 25 can optionally include forming the at least one integrated circuit device including a plurality of sides and wherein forming the at least one heat transfer structure comprises forming at least one heat transfer structure extending between each of the plurality sides of the at least one integrated circuit device and the at least one heat dissipation device.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An integrated circuit assembly, comprising:
an electronic substrate;
at least one integrated circuit device electrically attached to the electronic substrate;
at least one heat dissipation device attached to the electronic substrate, wherein the at least one heat dissipation device comprises a phase change material within a containment chamber; and
at least one heat transfer structure formed in or on the electronic substrate, wherein the at least one heat transfer structure extends between and thermally contacts the at least one integrated circuit device and the at least one heat dissipation device.

2. The integrated circuit assembly of claim 1, wherein the at least one integrated circuit device thermally contacts the at least one integrated circuit device through at least one interconnect.

3. The integrated circuit assembly of claim 1, wherein the at least one heat dissipation device comprises an inner sidewall surrounding the at least one integrated circuit device and an outer sidewall surrounding the inner sidewall, and a capping structure extending between the inner wall and the outer wall.

4. The integrated circuit assembly of claim 1, wherein the capping structure extends over the integrated circuit device.

5. The integrated circuit assembly of claim 4, wherein the capping structure is in thermal contact with the integrated circuit device by a thermal interface material disposed therebetween.

6. The integrated circuit assembly of claim 1, wherein the at least one heat dissipation device includes a plurality of containment chambers.

7. The integrated circuit assembly of claim 6, wherein one containment chamber of the plurality of containment chambers contains a phase change material and wherein another containment chamber of the plurality of containment chambers contains a different phase change material.

8. The integrated circuit assembly of claim 1, wherein the at least one heat transfer structure comprises a single structure substantially surrounding the at least one integrated circuit device.

9. The integrated circuit assembly of claim 1, wherein the at least one integrated circuit device includes a plurality of sides and wherein the at least one heat transfer structure comprises at least one heat transfer structure extending between each of the plurality sides of the at least one integrated circuit device and the at least one heat dissipation device.

10. An electronic system, comprising:
a board; and
an integrated circuit package electrically attached to the board, wherein the integrated circuit package comprises:
an electronic substrate;
at least one integrated circuit device electrically attached to the electronic substrate;
at least one heat dissipation device attached to the electronic substrate, wherein the at least one heat dissipation device comprises a phase change material within a containment chamber; and
at least one heat transfer structure formed in or on the electronic substrate, wherein the at least one heat transfer structure extends between and thermally contacts the at least one integrated circuit device and the at least one heat dissipation device.

11. The electronic system of claim 10, wherein the at least one integrated circuit device thermally contacts the at least one integrated circuit device through at least one interconnect.

12. The electronic system of claim 10, wherein the at least one heat dissipation device comprises an inner sidewall surrounding the at least one integrated circuit device and an outer sidewall surrounding the inner sidewall, and a capping structure extending between the inner wall and the outer wall.

13. The electronic system of claim 12, wherein the capping structure extends over the integrated circuit device.

14. The electronic system of claim 13, wherein the capping structure is in thermal contact with the integrated circuit device by a thermal interface material disposed therebetween.

15. The electronic system of claim 10, wherein the at least one heat dissipation device includes a plurality of containment chambers.

16. The electronic system of claim 15, wherein one containment chamber of the plurality of containment chambers contains a phase change material and wherein another containment chamber of the plurality of containment chambers contains a different phase change material.

17. The electronic system of claim 10, wherein the at least one heat transfer structure comprises a single structure substantially surrounding the at least one integrated circuit device.

18. The electronic system of claim 10, wherein the at least one integrated circuit device includes a plurality of sides and wherein the at least one heat transfer structure comprises at least one heat transfer structure extending between each of the plurality sides of the at least one integrated circuit device and the at least one heat dissipation device.

19. A method of fabricating an integrated circuit assembly, comprising:
forming an electronic substrate;
forming at least one heat transfer structure in or on the electronic substrate;
forming at least one sidewall extending from at least a portion of the at least one heat transfer structure;
forming at least one integrated circuit device;
electrically attaching the at least one integrated circuit device to the electronic substrate;
disposing a phase change material adjacent the at least one sidewall; and
attaching a capping structure to the at least one sidewall;
wherein the at least one sidewall, at least a portion of the at least one heat transfer structure, and the at least one capping structure define a containment chamber and wherein the phase change material is within the containment chamber.

20. The method of claim 19, wherein the at least one integrated circuit device thermally contacts the at least one integrated circuit device through at least one interconnect.

21. The method of claim 19, wherein forming at least one sidewall comprises forming an inner sidewall surrounding the at least one integrated circuit device and forming an outer sidewall surrounding the inner sidewall, and forming a capping structure extending between the inner wall and the outer wall.

22. The method of claim 21, wherein forming the capping structure comprises forming the capping structure to extend over the integrated circuit device, and further comprises thermally contacting the capping structure with the integrated circuit device by disposing a thermal interface material therebetween.

23. The method of claim 19, wherein forming the at least one heat dissipation device includes forming a plurality of containment chambers.

24. The method of claim 23, wherein one containment chamber of the plurality of containment chambers contains a phase change material and wherein another containment chamber of the plurality of containment chambers contains a different phase change material.

25. The method of claim 19, wherein forming the at least one integrated circuit device includes forming a plurality of sides of the integrated circuit device and wherein forming the at least one heat transfer structure comprises forming at least one heat transfer structure extending between each of the plurality sides of the at least one integrated circuit device and the at least one heat dissipation device.
